(19) United States
(12) Patent Application Publication
(10) Pub. No.: US 2025/0300046 A1
(43) Pub. Date: Sep. 25, 2025

(54) SEMICONDUCTOR DEVICE AND MANUFACTURING METHOD THEREFOR

(71) Applicant: FUJI ELECTRIC CO., LTD., Kawasaki-shi (JP)

(72) Inventors: Koji OSAKI, Matsumoto-city (JP); Yuichiro HINATA, Matsumoto-city (JP); Naoyuki KANAI, Matsumoto-city (JP); Ryoichi KATO, Matsumoto-city (JP)

(73) Assignee: FUJI ELECTRIC CO., LTD., Kawasaki-shi (JP)

(21) Appl. No.: 19/064,502

(22) Filed: Feb. 26, 2025

(30) Foreign Application Priority Data
Mar. 22, 2024 (JP) 2024-046522

(51) Int. Cl. H01L 23/498; H01L 23/053; H01L 23/06

(52) U.S. Cl. CPC H01L 23/49811; H01L 23/053; H01L 23/06

(57) ABSTRACT

A semiconductor device, including an insulated circuit board and a case. The case includes: a terminal holding part including a first inner surface, which defines a periphery of a housing area in which the insulated circuit board is housed, and a terminal integrally molded with the terminal holding part, and extending in a direction from the first inner surface toward the housing area in a plan view of the semiconductor device. The terminal includes: an inner bonding part bonded to a front surface of the insulated circuit board, the inner bonding part having a plurality of edges including a first edge that is closest to the first inner surface; and an inclined part rising at an angle to the terminal holding part from the first edge of the inner bonding part.

### CROSS-REFERENCE TO RELATED APPLICATION

This application is based upon and claims the benefit of priority of the prior Japanese Patent Application No. 2024-046522, filed on Mar. 22, 2024, the entire contents of which are incorporated herein by reference.

### BACKGROUND OF THE INVENTION

### 1. Field of the Invention

The embodiments discussed herein relate to a semiconductor device and a method for manufacturing the same.

### 2. Background of the Related Art

There are proposed semiconductor devices in which, in order to reduce inductance, an inclined part is provided in each electrode to shorten the length of the electrode (see, for example, Japanese Laid-open Patent Publication No. 2022-111597). There are also proposed semiconductor devices in which a portion of a terminal, bonded to a substrate electrode, is made thinner than other portions in order to relieve thermal stress on a bonding member and/or prevent the substrate electrode from being stripped off during ultrasonic bonding (see, for example, Japanese Patent No. 7170911 and Japanese Laid-open Patent Publication No. 2022-189515). There is yet another technology that provides, between a base substrate and each lead frame, a stress reduction part that relieves stress by causing partial stripping or shearing (see, for example, Japanese Laid-open Patent Publication No. 2017-203709).

### SUMMARY OF THE INVENTION

According to an aspect, there is provided a semiconductor device including an insulated circuit board; and a case, including: a terminal holding part including a first inner surface, which defines a periphery of a housing area in which the insulated circuit board is housed, and a terminal integrally molded with the terminal holding part, and extending in a direction from the first inner surface toward the housing area in a plan view of the semiconductor device, wherein the terminal includes an inner bonding part bonded to a front surface of the insulated circuit board, the inner bonding part having a plurality of edges including a first edge that is closest to the first inner surface, and an inclined part rising at an angle to the terminal holding part from the first edge of the inner bonding part.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a top view illustrating an example of a semiconductor device according to a first embodiment;

FIG. 2 is a cross-sectional view taken along a line II-II in FIG. 1;

FIG. 3 illustrates a circuit configuration of an example of a three-level inverter;

FIG. 4 is an enlarged cross-sectional view of a part in FIG. 2;

FIG. 5 is a cross-sectional view of a semiconductor device of a comparative example;

FIGS. 6A and 6B are simplified diagrams of a terminal according to the comparative example and a terminal according to the first embodiment;

FIG. 7 illustrates an example of locations of crack occurrence;

FIGS. 8A and 8B illustrate relationships between stress and a rising angle and thicknesses of terminals;

FIGS. 9A and 9B are plan views illustrating two examples of a terminal divided into multiple portions;

FIG. 10 is a cross-sectional view of a modification of the terminal;

FIG. 11 is a cross-sectional view illustrating a modification of a case;

FIG. 12 is a plan view depicting an appearance of the semiconductor device including a printed circuit board;

FIG. 13 is a cross-sectional view taken along a line XIII-XIII in FIG. 12;

FIG. 14 illustrates processes for manufacturing the semiconductor device; and

FIG. 15 is a cross-sectional view illustrating an example of a gate opening through which a sealing resin is injected in a sealing process.

### DETAILED DESCRIPTION OF THE INVENTION

Several embodiments will be described below with reference to the accompanying drawings.

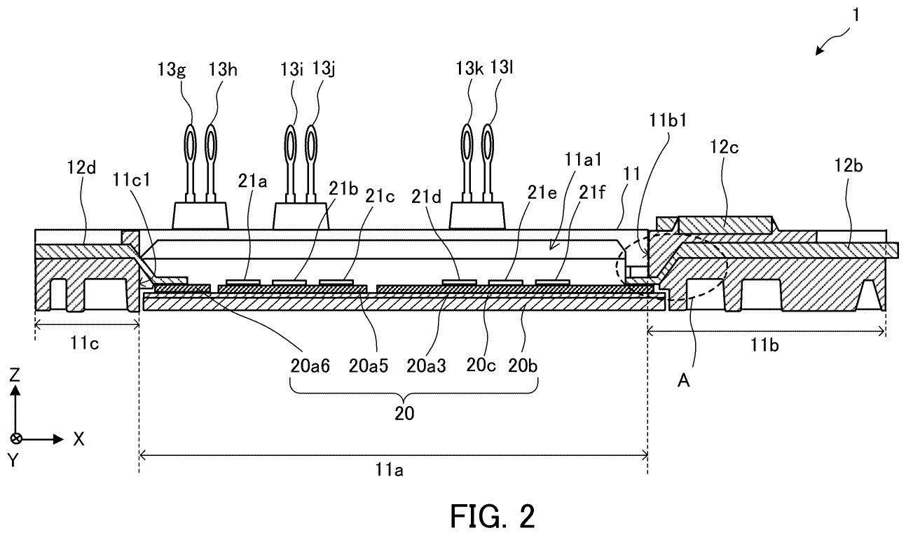

In the following, the terms “front surface” and “top surface” refer to the X-Y plane facing upward (in the +Z direction) in a semiconductor device 1 and the like of FIG. 2. Similarly, the term “upper” refers to the upward direction (the +Z direction) in the semiconductor device 1 and the like of FIG. 2. On the other hand, the terms “back surface” and “bottom surface” refer to the X-Y plane facing downward (in the −Z direction) in the semiconductor device 1 and the like of FIG. 2. Similarly, the term “lower” refers to the downward direction (the −Z direction) in the semiconductor device 1 and the like of FIG. 2. These terms have the same orientational relationships as described above in other drawings if needed. The terms “front surface”, “top surface”, “upper”, “back surface”, “bottom surface”, and “lower” are simply expedient expressions used to specify relative positional relationships, and are not intended to limit the technical ideas of the embodiments described herein. For example, the terms “upper” and “lower” do not necessarily imply the vertical direction to the ground surface. That is, the “upper” and “lower” directions are not defined in relation to the direction of the gravitational force.

### (a) First Embodiment

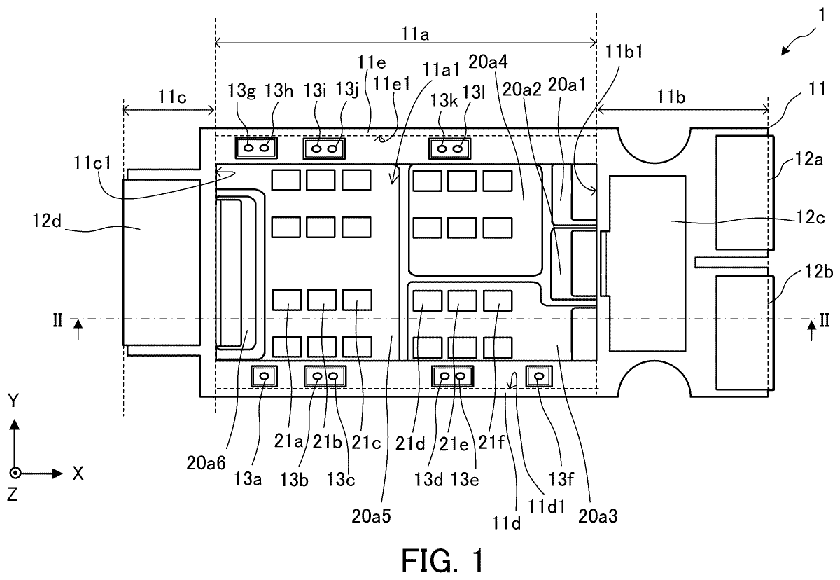

FIG. 1 is a top view illustrating an example of a semiconductor device according to a first embodiment. FIG. 2 is a cross-sectional view taken along a line II-II in FIG. 1. Note that FIGS. 1 and 2 omit illustrations of a sealing resin filled in a case 11 and connecting members, such as bonding wires. FIG. 2 illustrates not only a cross-sectional configuration along the line II-II, but also components visible in the +Y direction from the line II-II in FIG. 1.

The semiconductor device of the first embodiment is sometimes called a three-level inverter.

The semiconductor device 1 includes the case 11, an insulated circuit board 20, and multiple semiconductor elements. In FIG. 1, the multiple semiconductor elements are rectangular components in plan view mounted on conductive pattern layers 20a3 to 20a5 (to be described below), and reference numerals are given only to some semiconductor elements 21a to 21f.

The case 11 includes a housing space 11a and terminal holding parts 11b and 11c integrally connected to ±X-direction ends, respectively, of the housing space 11a. The housing space 11a has an opening on the top surface and includes side walls 11d and 11e individually provided on the ±Y-direction ends, respectively, of the top surface. The side walls 11d and 11e are provided along the longitudinal direction (i.e., the X direction), facing each other in the Y direction. One ends of the side walls 11d and 11e are integrally connected to the terminal holding part 11b and the other ends are integrally connected to the terminal holding part 11c. The housing space 11a may further include side walls individually connecting the +X-direction ends of the side walls 11d and 11e.

The housing space 11a described above includes a housing area 11a1 which is defined (surrounded) by the top surface and the side walls 11d and 11e as well as first inner surfaces 11b1 and 11c1 (of the terminal holding parts 11b and 11c) and second inner surfaces 11d1 and 11e1 to be described later. The housing area 11a1 houses therein the insulated circuit board 20.

The terminal holding parts 11b and 11c include the first inner surfaces 11b1 and 11cl each connected to the housing space 11a and defining the periphery of the housing area 11a1. The terminal holding parts 11b and 11c are provided at positions opposing each other in the X direction with the side walls 11d and 11e extending in the X direction therebetween. When the housing space 11a includes side walls connecting the #X direction ends of the side walls 11d and 11e, the first inner surfaces 11b1 and 11cl may be connected to the side walls and define the housing area 11a1 via the side walls.

Furthermore, the case 11 has terminals 12a to 12c which are integrally molded with the terminal holding part 11b, extend in a direction from the first inner surface 11b1 toward the housing area 11a1 in plan view, and are bonded to the insulated circuit board 20. At this time, the spaces between the terminals 12a to 12c are filled with the terminal holding part 11b. Herewith, insulation of each of the terminals 12a to 12c is maintained. In addition, the case 11 has a terminal 12d which is integrally molded with the terminal holding part 11c, extends, while being held by the terminal holding part 11c, in a direction from the first inner surface 11cl toward the housing area 11a1 in plan view, and is bonded to the insulated circuit board 20.

The case 11 is formed, for example, by injection molding using a thermoplastic resin. The thermoplastic resin is, for example, a polyphenylene sulfide resin, a polybutylene terephthalate resin, a polybutylene succinate resin, a polyamide resin, an acrylonitrile butadiene styrene resin, or a liquid crystal polymer.

The terminals 12a and 12b are external connection terminals for main current, to which different potentials are applied. In the following description, it is assumed that a negative terminal of a direct-current (DC) power supply is connected to the terminal 12a, and a positive terminal of the DC power supply is connected to the terminal 12b. The terminal 12c is called a neutral terminal (or intermediate terminal) of the three-level inverter. The terminal 12d is an output terminal. The terminals 12a to 12d are made of a material having excellent electrical conductivity. The material is, for example, aluminum, iron, silver, copper, or an alloy containing at least one of these.

Furthermore, the case 11 has terminals 13a to 13l. In the example of FIG. 1, the terminals 13a to 13l are provided in parts within the top surface of the case 11, which are individually connected to the upper ends of the side walls 11d and 11e, extend in the X direction, and partially cover the rectangular insulated circuit boards 20. One ends of the terminals 13a to 131 are exposed upward from the top surface of the case 11, and the other ends, although not illustrated, penetrate the top surface of the case 11 and protrude downward. The terminals 13a to 131 may also be integrally molded with the case 11 together with the terminals 12a to 12d. For example, press-fit pins may be used as the terminals 13a to 13l.

The insulated circuit board 20 has a rectangular shape in plan view. The insulated circuit board 20 includes conductive pattern layers 20a1 to 20a6, a metal layer 20b, and a resin layer 20c sandwiched between the conductive pattern layers 20a1 to 20a6 and the metal layer 20b.

The conductive pattern layers 20a1 to 20a6 are made of a metal having excellent electrical conductivity, such as copper, aluminum, or an alloy containing at least one of these.

In the example of FIGS. 1 and 2, the terminal 12a is bonded to the conductive pattern layer 20al, the terminal 12c is bonded to the conductive pattern layer 20a2, the terminal 12b is bonded to the conductive pattern layer 20a3, and the terminal 12d is bonded to the conductive pattern layer 20a6, individually with bonding members, such as solder. Note that illustrations of the bonding members are omitted from FIGS. 1 and 2. Instead of using the bonding members, the bonding may be achieved by ultrasonic bonding.

The metal layer 20b has a rectangular shape in plan view. The corners of the metal layer 20b may be R- or C-chamfered. The metal layer 20b is mainly made of a metal having excellent thermal conductivity. Such a metal is, for example, copper, aluminum, or an alloy containing at least one of these.

The resin layer 20c has a rectangular shape in plan view. The corners of the resin layer 20c may be R- or C-chamfered. The resin layer 20c is made of an insulating resin. The insulating resin may be a material having low thermal resistance and high insulation. Thermosetting resins and thermoplastic resins exhibit such properties. For example, at least one of the following thermosetting resins may be used: an epoxy resin; a cyanate resin; a polyimide resin; a benzoxazine resin; an unsaturated polyester resin; a phenol resin; a melamine resin; a silicone resin; and a maleimide resin. On the other hand, as a thermoplastic resin, for example, at least one of the following may be used: an acrylic resin; and a polyamide resin. These resins may contain fillers. The fillers are made of at least one of oxide and nitride. Examples of the oxide include silicon oxide and aluminum oxide. Examples of the nitride include silicon nitride, aluminum nitride, and boron nitride. Furthermore, hexagonal boron nitride may be used as the fillers.

In the insulated circuit board 20, an insulating plate containing ceramics as a main component may be used in place of the resin layer 20c. Such ceramics are made of a material containing aluminum oxide, aluminum nitride, or silicon nitride as a main component, for example. In this case, a direct copper bonding (DCB) board or an active metal brazed (AMB) board, for example, may be used as the insulated circuit board 20.

The multiple semiconductor elements (such as the semiconductor elements 21a to 21f) are mounted on the main surface of the insulated circuit board 20. The main surface of the insulated circuit board 20 is the front surfaces (top surfaces) of the conductive pattern layers 20a1 to 20a6. Although no illustration is given, each semiconductor element is joined to the front surface of one of the conductive pattern layers 20a3 to 20a5 using solder. In the example of FIG. 1, twelve semiconductor elements including the semiconductor elements 21a to 21c are joined to the conductive pattern layer 20a5, six semiconductor elements including the semiconductor elements 21d to 21f are joined to the conductive pattern layer 20a3, and six semiconductor elements are joined to the conductive pattern layer 20a4.

Each semiconductor element includes a switching element made of silicon, silicon carbide, or gallium nitride. The switching elements are, for example, insulated gate bipolar transistors (IGBTs) or power metal-oxide-semiconductor field-effect transistors (power MOSFETs). Each semiconductor element may be a reverse-conducting IGBT (RC-IGBT). The RC-IGBT has integrated functions of both an IGBT and a free wheeling diode (FWD). Alternatively, each semiconductor element may be a power MOSFET made of silicon carbide. In this case, body diodes of the power MOSFETs may perform the same function as the FWDs of the RC-IGBTs.

Although not illustrated in the drawings, a main electrode and a control electrode are provided on the front surface of each semiconductor element. When each semiconductor element is an IGBT, the main electrode is an emitter electrode, and when each semiconductor element is a power MOSFET, the main electrode is a source electrode. The main electrode on the front surface is electrically connected to the terminal 12a, 12c, or 12d via a connecting member (not illustrated). The control electrode is a gate electrode of the switching element included in each semiconductor element. The control electrode is electrically connected to one of the terminals 13a to 131 via a connecting member (not illustrated).

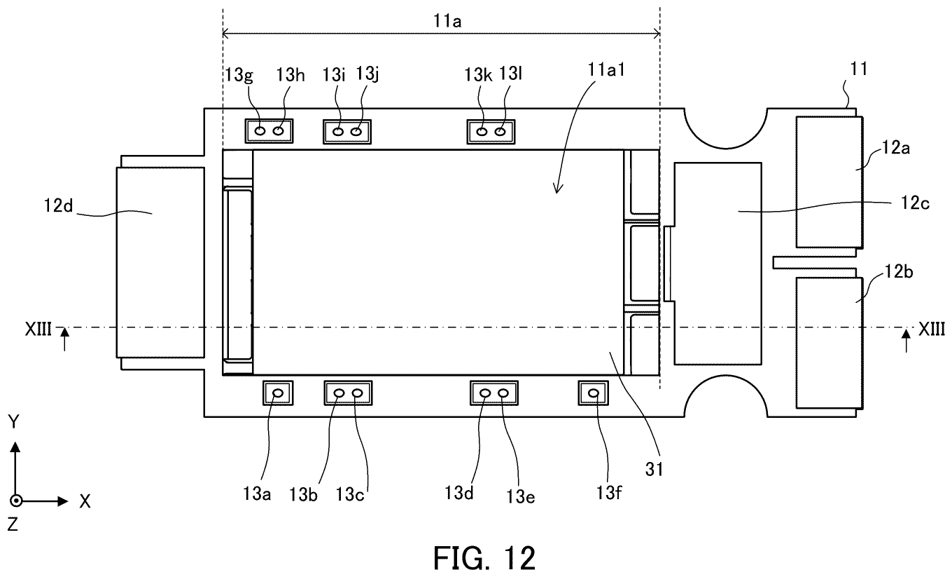

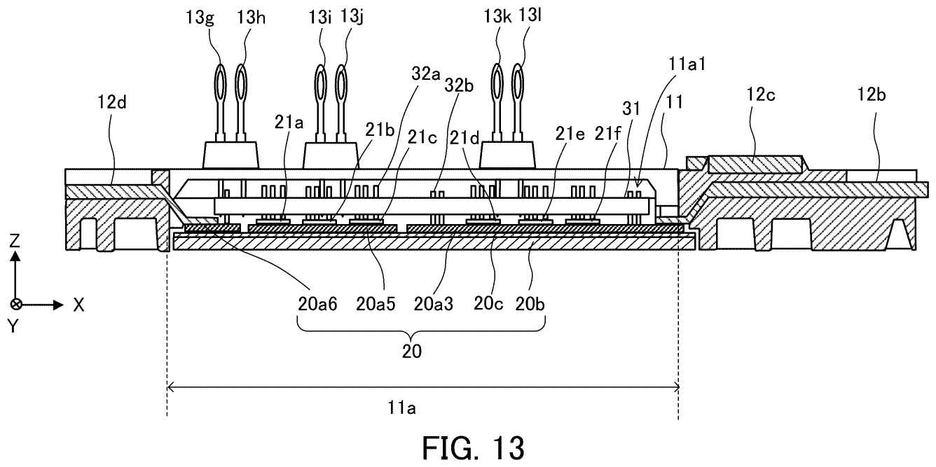

Although not illustrated in the drawings, each semiconductor element also has a main electrode on its back surface. When each semiconductor element is an IGBT, the main electrode on the back surface is a collector electrode, and when each semiconductor element is a power MOSFET, the main electrode on the back surface is a drain electrode. The main electrode on the back surface of each semiconductor element is electrically connected to the terminal 12b, the terminal 12d, or the main electrode on the back surface of another semiconductor element. As the connecting members, for example, bonding wires or a printed circuit board described later (see FIGS. 12 and 13) may be used.

The number of semiconductor elements is not limited to the above example. The number of semiconductor elements is determined according to the specifications and the like of the semiconductor device 1. In addition, other semiconductor elements, such as diode elements, may be provided on the insulated circuit board 20.

In the example of the semiconductor device 1 of FIGS. 1 and 2, the case 11 has an open top surface; however, the case 11 may cover the entire housing area 11a1 from above. The semiconductor device 1 may also have a lid member that covers the opening at the top of the case 11.

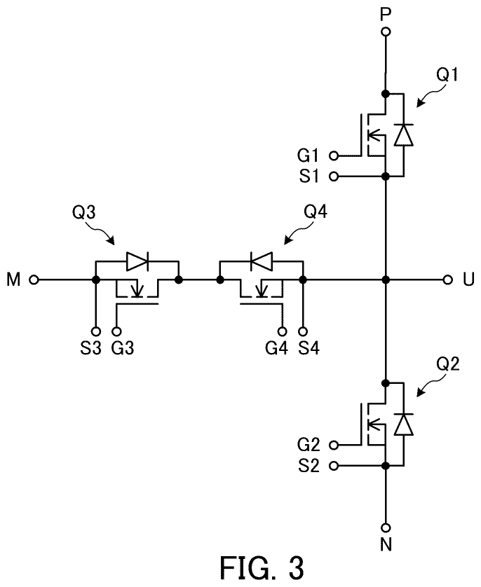

FIG. 3 illustrates a circuit configuration of an example of a three-level inverter.

The three-level inverter illustrated in FIG. 3 is a T-type neutral point clamped (NPC) inverter circuit, and includes four transistors Q1 to Q4. The transistor Q1 to Q4 are realized, for example, using the multiple semiconductor elements (the semiconductor elements 21a to 21f and the like) depicted in FIGS. 1 and 2.

The drain electrode of the transistor Q1 is connected to a P terminal, which is a positive input terminal. The P terminal corresponds to the terminal 12b of FIG. 1. The source electrode of the transistor Q2 is connected to an N terminal, which is a negative input terminal. The N terminal corresponds to the terminal 12a of FIG. 1.

The drain electrodes of the transistors Q3 and Q4 are connected to each other, and the source electrode of the transistor Q3 is connected to an M terminal (neutral terminal) which is an input terminal of an intermediate potential. The M terminal corresponds to the terminal 12c of FIG. 1.

The source electrode of the transistor Q1, the drain electrode of the transistor Q2, and the source electrode of the transistor Q4 are connected to a U terminal, which is an output terminal. The U terminal corresponds to the terminal 12d of FIG. 1.

The gate electrodes of the transistors Q1 to Q4 are respectively connected to gate terminals (terminals) G1 to G4, which are input terminals for control signals for switching operations. The gate terminals G1 to G4 each correspond to one of the terminals 13a to 131 of FIG. 1. The source electrodes of the transistors Q1 to Q4 are connected to auxiliary source terminals S1 to S4, which are output terminals. The auxiliary source terminals S1 to S4 each correspond to one of the terminals 13a to 131 of FIG. 1.

In the three-level inverter, when the control signals to the gate terminals G1 and G2 are ON and the control signals to the gate terminals G3 and G4 are OFF, the output voltage from the U terminal is E/2. When the control signals to the gate terminals G2 and G3 are ON and the control signals to the gate terminals G1 and G4 are OFF, the output voltage from the U terminal is 0. When the control signals to the gate terminals G3 and G4 are ON and the control signals to the gate terminals G1 and G2 are OFF, the output voltage from the U terminal is −E/2.

The terminals 12a to 12d included in the case 11 of the semiconductor device 1 of FIGS. 1 and 2 have a structure described below. In the following, the terminal 12b is described as an example; however, the terminals 12a 12c, and 12d may also have the same structure.

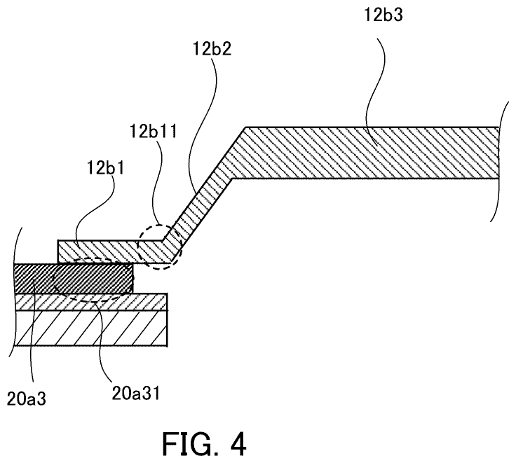

FIG. 4 is an enlarged cross-sectional view of a part in FIG. 2.

FIG. 4 illustrates the terminal 12b and its bonding portion in a region A in FIG. 2. As illustrated in FIG. 4, the terminal 12b has an inner bonding part 12b1, an inclined part 12b2, and an outer bonding part 12b3.

Note that, in FIG. 4, the inner bonding part 12b1, the inclined part 12b2, and the outer bonding part 12b3 are illustrated separately, but they are integrally connected to each other. In addition, the boundaries between the inner bonding part 12b1, the inclined part 12b2, and the outer bonding part 12b3 are merely examples, and are not limited to the example depicted in FIG. 4.

The inner bonding part 12b1 is bonded to the front surface of the insulated circuit board 20. Specifically, the inner bonding part 12b1 is provided at a second edge 20a31, which is closest to the first inner surface 11b1 amongst edges of the conductive pattern layer 20a3 included in the front surface of the insulated circuit board 20. The conductive pattern layer 20a3 itself is also formed close to the first inner surface 11b1 depicted in FIG. 2. In this case, a first edge 12b11 of the inner bonding part 12b1, to which the inclined part 12b2 is joined, may protrude from the second edge 20a31 of the conductive pattern layer 20a3 to the first inner surface 11b1 side. That is, not necessarily the entire bottom surface of the inner bonding part 12b1 but only a part of the bottom surface may be bonded to the conductive pattern layer 20a3. At this time, below (in the −Z direction) the portion of the inner bonding part 12b1, which protrudes from the second edge 20a31 of the conductive pattern layer 20a3, a space is defined by being surrounded by the second edge 20a31 of the conductive pattern layer 20a3 and the resin layer 20c. The first edge 12b11 of the inner bonding part 12b1 may be located on the inner side (in the +X direction) of the first inner surface 11b1 of the terminal holding part 11b of the integrally molded case 11 (see FIG. 2). Therefore, the top surface of the inner bonding part 12b1 may be partially covered by the terminal holding part 11b.

The inclined part 12b2 rises at an angle to the terminal holding part 11b from the first edge 12b11 of the inner bonding part 12b1, which is closest to the first inner surface 11b1 of the case 11. The rising angle of the inclined part 12b2 to the top surface of the inner bonding part 12b1 may be 35° or more and 70° or less, and may be about 45°.

At least a portion of the outer bonding part 12b3 is exposed from the case 11. The inner bonding part 12b1 and the inclined part 12b2 are thinner in thickness than the outer bonding part 12b3.

The terminals 12a, 12c, and 12d may have the same structure as the terminal 12b. That is, the terminals 12a, 12c, and 12d may each have an inner bonding part, an inclined part, and an outer bonding part, and these parts may be integrally formed.

In this case, the inner bonding part of the terminal 12a is provided at a second edge, which is closest to the first inner surface 11b1 amongst edges of the conductive pattern layer 20a1 included in the front surface of the insulated circuit board 20. The conductive pattern layer 20a1 itself is also formed close to the first inner surface 11b1. The inclined part of the terminal 12a rises at an angle to the terminal holding part 11b from a first edge of the inner bonding part, which is closest to the first inner surface 11b1 of the case 11. The inner bonding part of the terminal 12c is provided at a second edge, which is closest to the first inner surface 11b1 amongst edges of the conductive pattern layer 20a2 included in the front surface of the insulated circuit board 20. The conductive pattern layer 20a2 itself is also formed close to the first inner surface 11b1. The inner bonding part of the terminal 12d is provided at a second edge, which is closest to the first inner surface 11cl opposing the first inner surface 11b1 in the X direction amongst edges of the conductive pattern layer 20a6 included in the front surface of the insulated circuit board 20. The conductive pattern layer 20a6 itself is also formed close to the first inner surface 11c1.

The inclined part of the terminal 12c rises at an angle to the terminal holding part 11b from a first edge of the inner bonding part, which is closest to the first inner surface 11b1 of the case 11. The inclined part of the terminal 12d rises at an angle to the terminal holding part 11c from a first edge of the inner bonding part, which is closest to the first inner surface 11cl of the case 11.

Note that one or more of the terminals 12a to 12d may have the above-described structure.

Effects of using terminals with the above-described structure are described next in comparison with a semiconductor device of a comparative example.

### (Semiconductor Device of Comparative Example and Problems Thereof)

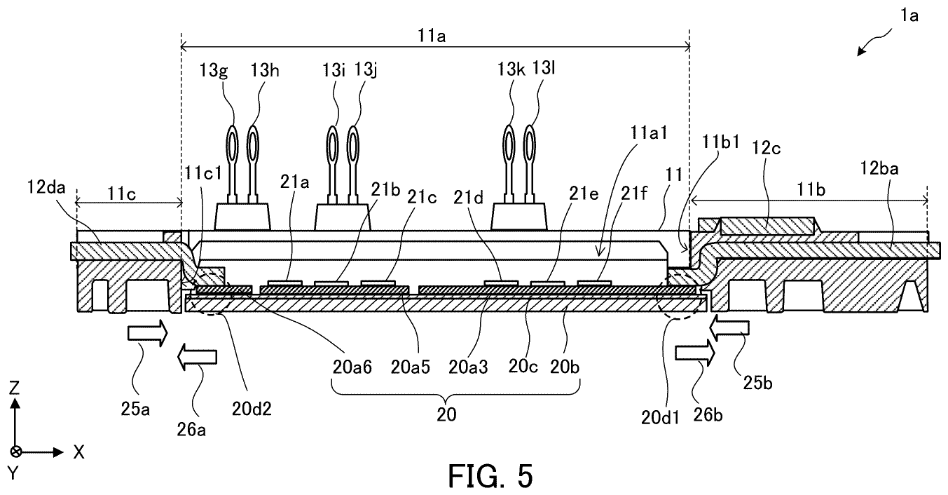

FIG. 5 is a cross-sectional view of a semiconductor device of a comparative example.

FIG. 5 depicts a cross section of a semiconductor device 1a of the comparative example, corresponding to the cross section of the semiconductor device 1 of FIG. 2. In FIG. 5, like reference numerals refer to identical components depicted in FIG. 2.

In the semiconductor device 1a of the comparative example, terminals 12ba and 12da have structures different from those of the terminals 12b and 12d illustrated in FIG. 2. Each of the terminals 12ba and 12da rises almost at a right angle from a portion joined to the front surface of the insulated circuit board 20. In addition, the terminals 12ba and 12da have a uniform thickness throughout.

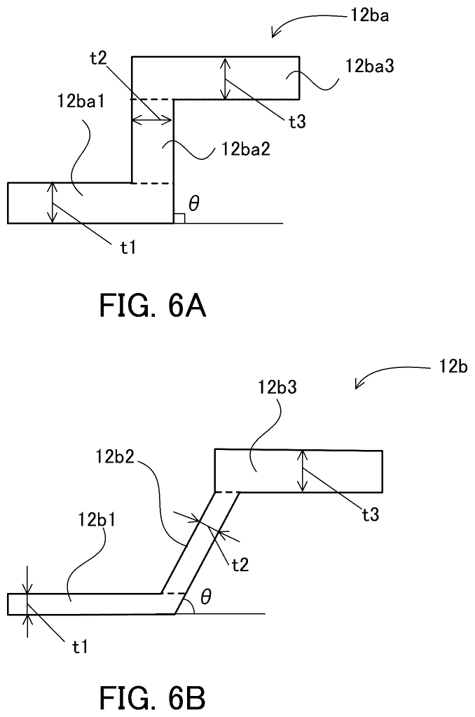

FIGS. 6A and 6B are simplified diagrams of a terminal according to the comparative example and a terminal according to the first embodiment. FIG. 6A is a simplified diagram of the terminal 12ba of the semiconductor device 1a of the comparative example, and FIG. 6B is a simplified diagram of the terminal 12b of the semiconductor device 1 according to the first embodiment.

The terminal 12ba includes an inner bonding part 12ba1 bonded to the front surface of the insulated circuit board 20, a rising part 12ba2, and an outer bonding part 12ba3. A rising angle θ of the rising part 12ba2 is 90°. In addition, a thickness t1 of the inner bonding part 12ba1, a thickness t2 of the rising part 12ba2, and a thickness t3 of the outer bonding part 12ba3 are all equal to each other.

The terminal 12b includes the inner bonding part 12b1, the inclined part 12b2, and the outer bonding part 12b3. The rising angle θ of the inclined part 12b2 is less than 90°, for example, θ=45°. In addition, the thickness t1 of the inner bonding part 12b1 and the thickness t2 of the inclined part 12b2 are less than the thickness t3 of the outer bonding part 12b3. The thicknesses t1 and t2 are equal to each other.

In the semiconductor device 1a of the comparative example, the following problems occur during manufacturing. In a sealing process, the semiconductor device 1a with no sealing resin filled therein is clamped to a mold, and after the temperature is raised, a sealing resin is filled into the case 11. The temperature rise at this time causes the case 11 to expand in the directions of arrows 25a and 25b in FIG. 5, that is, toward the housing area 11al. On the other hand, the insulated circuit board 20 expands in the directions of arrows 26a and 26b in FIG. 5, that is, in the outward direction of the case 11. Due to such deformation (sometimes called shear deformation), stress is concentrated, within the insulated circuit board 20, in regions 20d1 and 20d2 where the terminals 12ba and 12da are bonded. This may cause the terminals 12ba and 12da to be stripped off from the insulated circuit board 20. In addition, due to the stress concentration in the regions 20d1 and 20d2, cracks may occur in the resin layer 20c, which is an insulating layer of the insulated circuit board 20.

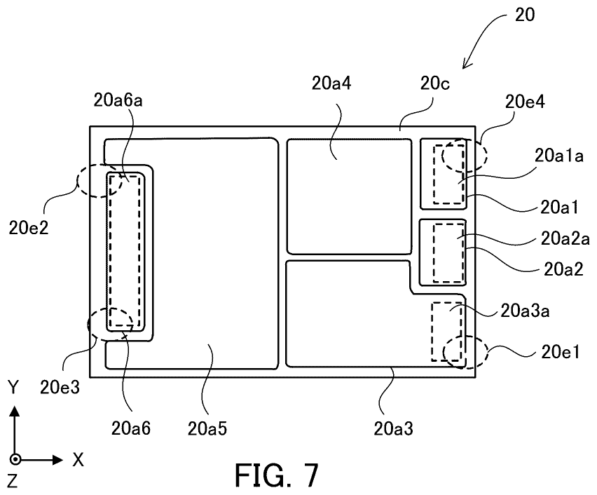

FIG. 7 illustrates an example of locations of crack occurrence.

FIG. 7 depicts the conductive pattern layers 20al to 20a6 on the front surface of the insulated circuit board 20 and terminal bonding regions 20a1a, 20a2a, 20a3a, and 20a6a in the conductive pattern layers 20a1, 20a2, 20a3, and 20a6. For example, the terminal 12ba illustrated in FIG. 5 is bonded to the terminal bonding region 20a3a of the conductive pattern layer 20a3, and the terminal 12da illustrated in FIG. 5 is bonded to the terminal bonding region 20a6a of the conductive pattern layer 20a6.

When stress is concentrated in the regions 20d1 and 20d2 as illustrated in FIG. 5, cracks may occur in the resin layer 20c, for example, in regions 20e1, 20e2, and 20e3 in FIG. 7. In addition, when the terminal to which the negative terminal of the DC power supply is connected has a structure similar to that of the terminal 12ba, cracks may occur, for example, in a region 20e4.

Note that, in the insulated circuit board 20, regions closer to the long sides (the +Y direction sides) are more susceptible not only to the effect of the expansion of the terminal holding part 11b or 11c of the case 11, but also to the effect of the expansion of the side wall 11d or 11e. Therefore, the regions 20e1 to 20e4 where cracks may occur are found closer to the long sides of the insulated circuit board 20 as depicted in FIG. 7.

### Effects of Semiconductor Device 1 of First Embodiment

In the semiconductor device 1 according to the first embodiment in contrast to the semiconductor device 1a of the comparative example, for example, the terminal 12b is less susceptible to deformation due to the expansion of the case 11 because of having the inclined part 12b2 as illustrated in FIGS. 4 and 6B. This is thought to be because the inclined part 12b2 exerts an effect like a damper. That is, the inclined part 12b2 is more readily deflected than the rising part 12ba2, and even if stress occurs in the +X direction at both ends of the inclined part 12b2, the inclined part 12b2 is therefore able to buffer the stress. This relieves the stress applied to the region of the insulated circuit board 20, directly below the inner bonding part 12b1. This in turn prevents the terminal 12b from being stripped off from the insulated circuit board 20. In addition, it is possible to prevent cracks in the resin layer 20c, which is an insulating layer of the insulated circuit board 20.

As described above, the inner bonding part 12b1 is provided at the second edge 20a31, which is closest to the first inner surface 11b1 amongst the edges of the conductive pattern layer 20a3 included in the front surface of the insulated circuit board 20. Note that the conductive pattern layer 20a3 is formed close to the first inner surface 11b1 depicted in FIG. 2. In addition, the inner bonding part 12b1 is provided close to the first inner surface 11b1.

When the inner bonding part 12b1 is provided at a position close to the second edge 20a31 and/or the first inner surface 11b1, stress is likely to concentrate due to the influence of the expansion of the case 11. However, by providing the above-described inclined part 12b2 in the terminal 12b, it is possible to relieve the stress even at such a location where stress is likely to concentrate.

In addition, the rigidity of the terminal 12b is reduced by making the inner bonding part 12b1 thinner in thickness than the outer bonding part 12b3, thereby further relieving the stress on the region of the insulated circuit board 20, directly below the inner bonding part 12b1.

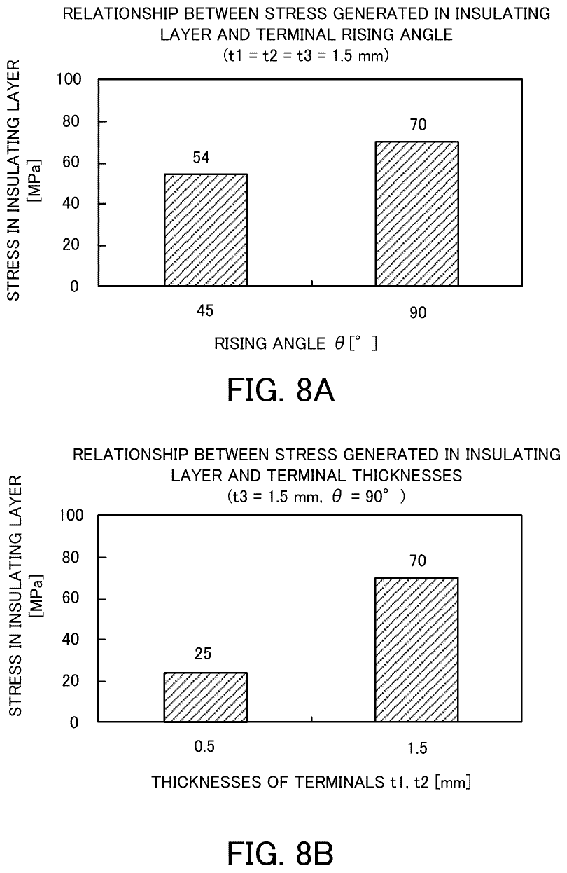

FIGS. 8A and 8B illustrate relationships between stress and the rising angle and thicknesses of terminals.

The relationships between stress and the rising angle and thicknesses of terminals in FIGS. 8A and 8B have been obtained by simulation. Temperature load conditions used here are simulated molding conditions.

FIG. 8A depicts the relationship between the rising angle θ of the terminals 12ba and 12b as illustrated in FIGS. 6A and 6B and stress applied to an insulating layer (corresponding to the resin layer 20c of the insulated circuit board 20). In FIG. 8A, the horizontal axis represents the rising angle [°] of the terminals, and the vertical axis represents the stress [MPa] applied to the insulating layer. Two rising angles are used in the simulation: In FIG. 8A, the thicknesses t1 to t3 of the terminals 12ba and 12b depicted in FIGS. 6A and 6B are all constant at 1.5 mm.

When the rising angle θ is 90°, the stress applied to the insulating layer is 70 MPa, whereas when the rising angle θ is 45°, the stress applied to the insulating layer is 54 MPa. That is, when the rising angle θ is 45°, the stress is reduced by about 23% compared to when the rising angle θ is 90°.

FIG. 8B depicts the relationship between the thicknesses of the terminals 12ba and 12b as illustrated in FIGS. 6A and 6B and the stress applied to an insulating layer (corresponding to the resin layer 20c of the insulated circuit board 20). In FIG. 8B, the thicknesses of the terminals are the thicknesses t1 and t2 of the terminals 12ba and 12b of FIGS. 6A and 6B. The thickness t3 is constant at 1.5 mm.

In FIG. 8B, the horizontal axis represents the thicknesses t1 and t2 [mm] of the terminals, and the vertical axis represents the stress [MPa] of the insulating layer. In the simulation, two different thicknesses are used for the thicknesses t1 and t2 of the terminals: 0.5 mm and 1.5 mm. The rising angle θ is constant at 90°.

When the thicknesses t1 and t2 are 1.5 mm, the stress applied to the insulating layer is 70 MPa, whereas when the thicknesses t1 and t2 are 0.5 mm, the stress applied to the insulating layer is 25 MPa. That is, when the thicknesses t1 and t2 are 0.5 mm, the stress is reduced by about 64% compared to when the thicknesses t1 and t2 are 1.5 mm.

From the simulation results of FIG. 8A, it is seen that by providing the inclined part 12b2 as in the terminal 12b of FIG. 6B and setting the rising angle θ to less than 90°, the stress is reduced compared to the case of using the terminal 12ba of FIG. 6A with a rising angle θ of 90°.

In addition, from the simulation results of FIG. 8B, it is seen that by making the thicknesses t1 and t2 of the inner bonding part 12b1 and the inclined part 12b2 less than the thickness t3 of the outer bonding part 12b3, the stress is reduced compared to the case of using the terminal 12ba of FIG. 6A.

### (b) Second Embodiment

A semiconductor device of a second embodiment is described next. In the semiconductor device according to the second embodiment, the inner bonding part and the inclined part of at least one of the terminals 12a to 12d in the semiconductor device 1 of the first embodiment are respectively divided into multiple parts in plan view. The remaining configuration of the semiconductor device of the second embodiment is the same as that of the semiconductor device 1 of the first embodiment, and a repeated description is therefore omitted.

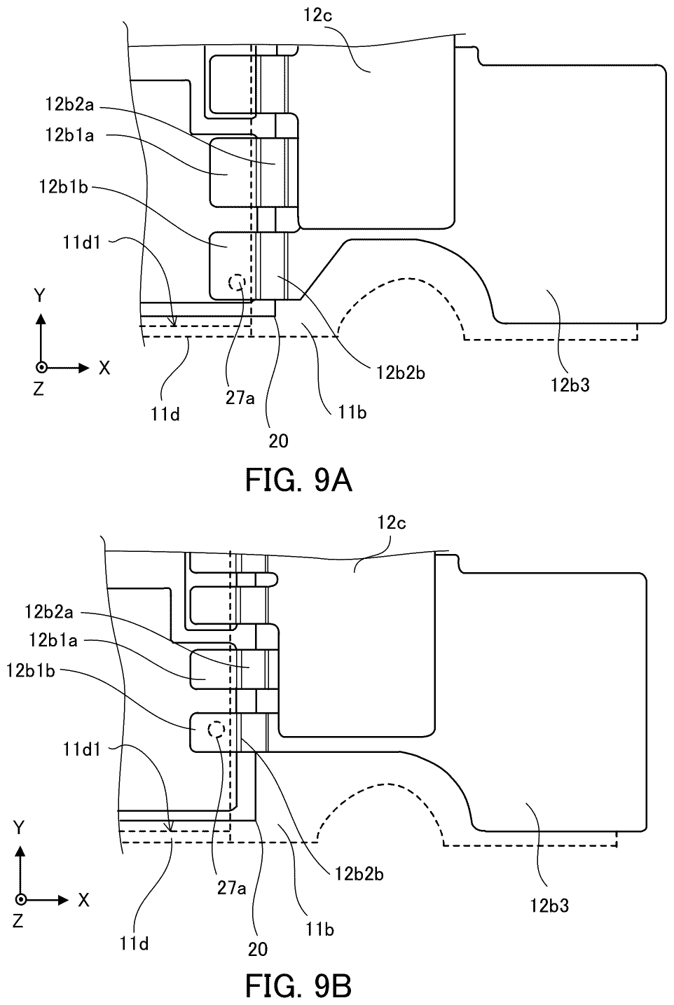

FIGS. 9A and 9B are plan views illustrating two examples of a terminal divided into multiple parts. In FIGS. 9A and 9B, like reference numerals refer to identical components of the semiconductor device 1 of the first embodiment depicted in FIGS. 1 and 2.

In the first example of the terminal division depicted in FIG. 9A, in the terminal 12b, the inner bonding part 12b1 and the inclined part 12b2 of FIG. 4 are each divided into two parts in the Y direction in plan view. That is, the inner bonding part 12b1 is divided into parts 12b1a and 12b1b, and the inclined part 12b2 is divided into parts 12b2a and 12b2b.

By dividing the terminals in this manner, the stress applied to the insulated circuit board 20 is dispersed, which prevents detachment of the terminals and cracks in the resin layer 20c.

Note however that the location of a region 27a in the insulated circuit board 20 directly below the part 12b1b in FIG. 9A is close to the second inner surface 11d1 of the side wall 11d of the case 11. In this case, the region 27a is affected not only by the expansion of the terminal holding part 11b of the case 11 but also by the expansion of the side wall 11d, and thus stress is likely to concentrate in the region 27a.

In the second example of the terminal division depicted in FIG. 9B, the inner bonding part 12b1 and the inclined part 12b2 of the terminal 12b illustrated in FIG. 4 are each divided into two parts in the Y direction in plan view, as in FIG. 9A. However, in FIG. 9B, the part 12b1b is disposed at a position farther away from the second inner surface 11d1 of the side wall 11d in the +Y direction than in the example of FIG. 9A. That is, the inner bonding part 12b1 made up of the parts 12b1a and 12b1b is disposed at a position farther away from the second inner surface 11d1 in the +Y direction than in the example of FIG. 9A.

Herewith, for example, the region 27a of the insulated circuit board 20 directly below the part 12b1b is less susceptible to the effect of the expansion of the side wall 11d, and stress applied to the region 27a is thus reduced.

### (Modification of Terminal)

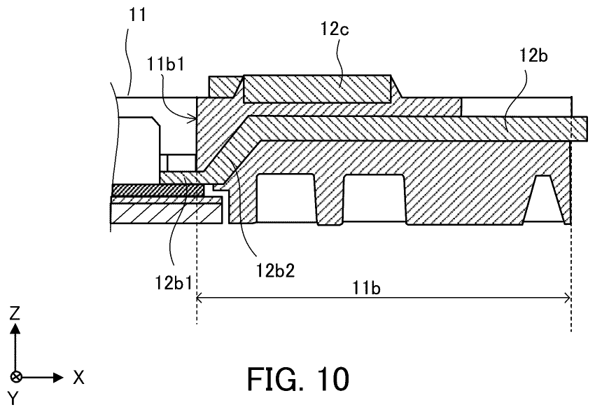

FIG. 10 is a cross-sectional view of a modification of a terminal.

In the terminal 12b depicted in FIGS. 4 and 6B, the thickness t1 of the inner bonding part 12b1 and the thickness t2 of the inclined part 12b2 are less than the thickness t3 of the outer bonding part 12b3. On the other hand, in the terminal 12b of the modification, only the inner bonding part 12b1 is thinner in thickness than the outer bonding part 12b3.

Also with terminal 12b the having the aforementioned structure, the rigidity is lowered due to the reduced thickness of the inner bonding part 12b1. As a result, the effect of reducing stress is expected.

Not only the terminal 12b, but also the terminals 12a and 12c may have the same structure as the terminal 12b. Similarly, for the terminal 12d, only the inner bonding part needs to be thinner than the outer bonding part, unlike the cross-sectional view depicted in FIG. 2.

### Modification of Case

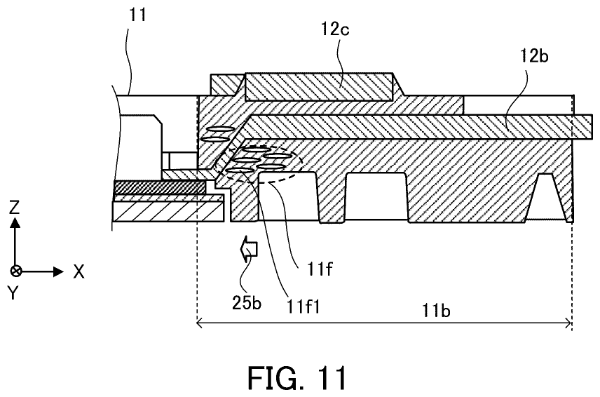

FIG. 11 is a cross-sectional view illustrating a modification of a case.

The case 11 may include fibrous fillers (for example, fillers 11f1), as depicted in FIG. 11. The fillers are added to a thermoplastic resin at the time of molding the case 11. For example, a glass fiber or carbon fiber may be used as the fibrous fillers.

The case 11 has a region 11f in the terminal holding part 11b where the fiber direction of the fillers coincides with the direction in which the terminal 12b extends (the X direction). The region 11f may be realized by directing the flow of the resin in the X direction during molding of the case 11.

In the region 11f, because the linear expansion coefficient in the X direction is small, expansion in the direction of the arrow 25b (the −X direction) is suppressed. As a result, the terminal 12b is less susceptible to deformation due to expansion of the case 11. This relieves stress on the region of the insulated circuit board 20 directly below the inner bonding part 12b1.

### (Example of Connecting Member)

As an example of the connecting member, a printed circuit board described below may be used.

FIG. 12 is a plan view depicting an appearance of a semiconductor device including a printed circuit board. FIG. 13 is a cross-sectional view taken along a line XIII-XIII in FIG. 12. FIG. 13 illustrates not only the cross-section configuration along the line XIII-XIII in FIG. 12, but also components visible in the +Y direction from the line XIII-XIII in FIG. 12. Note that the sealing resin filled in the case 11 is also omitted from FIGS. 12 and 13. In FIGS. 12 and 13, like reference numerals refer to identical components depicted in FIGS. 1 and 2.

A printed circuit board 31 is, for example, a multi-layered printed circuit board (PCB). In the printed circuit board 31, for example, a wiring layer may be formed on at least one of the top surface and the bottom surface of an insulating layer, and one or more wiring layers may further be formed inside the insulating layer.

The insulating layer is made of, for example, an insulating resin. A resin layer using an insulating resin is, for example, a paper phenol substrate, paper epoxy substrate, glass composite substrate, or glass epoxy substrate. The wiring layers are made of a metal having excellent electrical conductivity. Such a metal is, for example, copper, aluminum, or an alloy containing at least one of these as a major component.

The printed circuit board 31 is provided above the insulated circuit board 20 in the housing area 11a1 of the case 11. Although no illustration is given, the printed circuit board 31 is provided with multiple wiring holes. Objects inserted into the multiple wiring holes are main electrodes and control electrodes (not illustrated) on the top surfaces of the semiconductor elements (such as the semiconductor elements 21a to 21f in FIG. 13) and pin-shaped connecting members (for example, connecting members 32a and 32b) joined to the insulated circuit board 20. Such pin-shaped connecting members are sometimes called conductive posts. The pin-shaped connecting members are made of a metal having excellent conductivity.

The ends of the terminals 13a to 131 on the −Z direction side are also inserted into the wiring holes. Each wiring hole is connected to one of the wiring layers formed on the printed circuit board 31.

By using the aforementioned printed circuit board 31, the terminals 12a to 12d may be individually connected to one of the multiple semiconductor elements via the pin-shaped connecting members and the wiring layers of the printed circuit board 31. In addition, the terminals 13a to 131 may be individually and electrically connected to one of the multiple semiconductor elements via the pin-shaped connecting members and the wiring layers of the printed circuit board 31.

### (Method of Manufacturing Semiconductor Device)

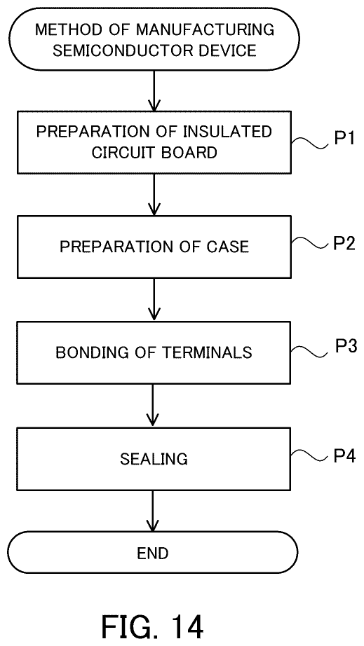

FIG. 14 illustrates processes for manufacturing a semiconductor device.

[Process P1] First, the insulated circuit board 20 is prepared. In process P1, the insulated circuit board 20 as illustrated in FIGS. 1 and 2 is prepared. That is, the insulated circuit board 20 includes the conductive pattern layers 20a1 to 20a6, the metal layer 20b, and the resin layer 20c sandwiched between the conductive pattern layers 20a1 to 20a6 and the metal layer 20b.

[Process P2] Second, the case 11 is prepared. For example, the case 11 is produced by filling a resin into a predetermined mold in which the terminals 12a to 12d and the terminals 13a to 131 are set. As described above, the case 11 includes the terminal holding parts 11b and 11c which include the first inner surfaces 11b1 and 11c1 defining, within the housing space 11a, the periphery of the housing area 11a1 in which the insulated circuit board 20 is housed. The case 11 also includes the terminals 12a to 12c that are integrally molded with the terminal holding part 11b, extend, while being held by the terminal holding part 11b, in a direction from the first inner surface 11b1 toward the housing area 11a1 in plan view, and are bonded to the insulated circuit board 20. In addition, the case 11 further includes the terminal 12d that is integrally molded with the terminal holding part 11c, extends, while being held by the terminal holding part 11c, in a direction from the first inner surface 11cl toward the housing area 11a1 in plan view, and is bonded to the insulated circuit board 20. Furthermore, the terminals 13a to 131 are provided in parts within the top surface of the case 11, which are individually connected to the upper ends of the side walls 11d and 11e, extend in the X direction, and partially cover the rectangular insulated circuit boards 20.

Amongst the terminals 12a to 12d, for example, the terminal 12b includes the inner bonding part 12b1 bonded to the front surface of the insulated circuit board 20 and the inclined part 12b2, as illustrated in FIG. 4. The inclined part 12b2 rises at an angle to the terminal holding part 11b from the first edge 12b11 of the inner bonding part 12b1, which is closest to the first inner surface 11b1 of the case 11.

Note that the order of processes P1 and P2 may be reversed. In addition, when the printed circuit board 31 is used as a connecting member, the printed circuit board 31 as illustrated in FIGS. 12 and 13 is also prepared.

[Process P3] Third, the insulated circuit board 20 is placed in the housing area 11a1 of the housing space 11a and the terminals 12a to 12d are bonded to the insulated circuit board 20. In this process, the terminals 12a to 12d are bonded to the insulated circuit board 20 using bonding members such as solder. Bonding of the individual semiconductor elements to the insulated circuit board 20 may also be performed at the same time.

[Process P4] Following the bonding process, the case 11 with the insulated circuit board 20 disposed therein is placed in a mold, and the inside of the case 11 is sealed with a sealing resin. In this sealing process, the semiconductor device 1 with no sealing resin filled therein is clamped to the mold, and after the temperature is raised, the sealing resin is filled into the case 11. A thermosetting used as the sealing resin. The thermosetting resin is, for example, an epoxy resin. When a lid member is used to cover the opening on the top surface of the case 11, the sealing resin is filled into the case 11 with the lid member adhered to the top surface of the case 11 so as to cover the opening.

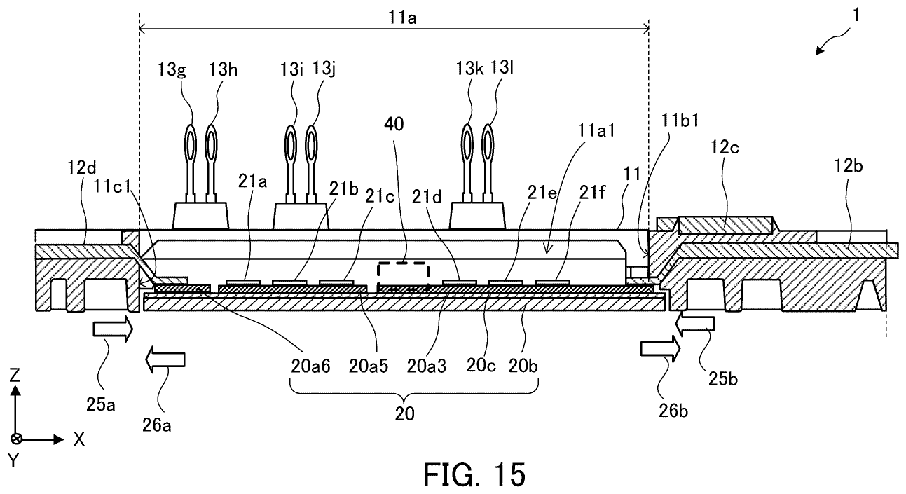

FIG. 15 is a cross-sectional view illustrating an example of a gate opening through which the sealing resin is injected in the sealing process. A gate opening 40 is provided, for example, near the center of the long side of the case 11 (corresponding to the center area of the length of the side wall 11d in the X direction in FIG. 1). The sealing resin is injected from the gate opening 40.

Due to the temperature rise in the sealing process, the case 11 expands in the directions of the arrows 25a and 25b, that is, toward the housing area 11al. On the other hand, the insulated circuit board 20 expands in the directions of the arrows 26a and 26b, that is, toward the outside of the case 11.

However, for example, the terminal 12b is less susceptible to deformation due to expansion of the case 11 because of having the inclined part 12b2 as illustrated in FIGS. 4 and 6B. This relieves stress on the region of the insulated circuit board 20 directly below the inner bonding part 12b1, which in turn prevents the terminal 12b from being stripped off from the insulated circuit board 20. In addition, it is possible to prevent cracks in the resin layer 20c, which is an insulating layer of the insulated circuit board 20. Furthermore, by making the inner bonding part 12b1 thinner in thickness than the outer bonding part 12b3, the rigidity of the terminal 12b is reduced. This further relieves stress on the region of the insulated circuit board 20 directly below the inner bonding part 12b1.

After the sealing resin filled into the case 11 is cured, the mold is removed to obtain the semiconductor device 1 of FIGS. 1 and 2. The semiconductor device according to the second embodiment in which the terminals are divided into multiple parts as depicted in FIGS. 9A and 9B may also be manufactured by the same processes as above.

Having described aspects of the semiconductor device and manufacturing method therefor based on the embodiments above, they are merely examples and the particular details of these illustrative examples shall not be construed as limitations on the appended claims.

According to an aspect, it is possible to prevent detachment of terminals of a semiconductor device during manufacturing.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
an insulated circuit board; and
a case, including:
a terminal holding part including a first inner surface, which defines a periphery of a housing area in which the insulated circuit board is housed, and
a terminal integrally molded with the terminal holding part, and extending in a direction from the first inner surface toward the housing area in a plan view of the semiconductor device, wherein
the terminal includes
an inner bonding part bonded to a front surface of the insulated circuit board, the inner bonding part having a plurality of edges including a first edge that is closest to the first inner surface, and
an inclined part rising at an angle to the terminal holding part from the first edge of the inner bonding part.

2. The semiconductor device according to claim 1, wherein:
the insulated circuit board includes, on the front surface thereof, a conductive pattern layer adjacent to the first inner surface, the conductive pattern layer having a plurality of edges including a second edge that is closest to the first inner surface, and
the inner bonding part is provided at the second edge of the conductive pattern layer.

3. The semiconductor device according to claim 1, wherein:
the terminal further has an outer bonding part exposed from the case, and
the inner bonding part and the inclined part of the terminal are thinner in thickness than the outer bonding part.

4. The semiconductor device according to claim 1, wherein:
the terminal has an outer bonding part exposed from the case, and
the inner bonding part, but not the inclined part, of the terminal is thinner in thickness than the outer bonding part.

5. The semiconductor device according to claim 1, wherein:
the inner bonding part of the terminal is disposed adjacent to the first inner surface of the case.

6. The semiconductor device according to claim 1, wherein:
the case further has a side wall which is connected to the terminal holding part, the side wall including a second inner surface that defines the periphery of the housing area, and
the inner bonding part is disposed at a position away from the second inner surface.

7. The semiconductor device according to claim 1, wherein:
each of the inner bonding part and the inclined part of the terminal is divided into a plurality of parts in the plan view.

8. The semiconductor device according to claim 1, wherein:
the insulated circuit board includes
a conductive pattern layer,
a metal layer, and
a resin layer sandwiched between the conductive pattern layer and the metal layer.

9. The semiconductor device according to claim 1, wherein:
the case further includes fibrous fillers, which,
in a region of the terminal holding part, have a fiber direction coinciding with a direction in which the terminal extends.

10. A method of manufacturing a semiconductor device, comprising:
preparing an insulated circuit board;
preparing a case including:
a terminal holding part including a first inner surface, which defines a periphery of a housing area for housing therein the insulated circuit board, and
a terminal integrally molded with the terminal holding part, and extending in a direction from the first inner surface toward the housing area in a plan view of the semiconductor device;
placing the insulated circuit board in the housing area and bonding the terminal to the insulated circuit board; and
placing, in a mold, the case with the insulated circuit board disposed therein and sealing an inside of the case with a sealing resin, wherein:
the terminal includes
an inner bonding part, by which the terminal is bonded to a front surface of the insulated circuit board, the inner bonding part having a plurality of edges including a first edge that is closest to the first inner surface, and
an inclined part rising at an angle to the terminal holding part from the first edge of the inner bonding part.
